(19) United States
(12) Patent Application Publication
(10) Pub. No.: US 2005/0122119 A1
(43) Pub. Date: Jun. 9, 2005

(54) Low noise proximity sensing system

(75) Inventor: George H. Barlow, Kirksville, MO (US)

Correspondence Address: SCHWEGMAN, LUNDBERG, WOESSNER & KLUTH, P.A., P.O. BOX 2938, MINNEAPOLIS, MN, 55402, US

(73) Assignee: Touchram LLC

(21) Appl. No.: 10/729,699

(22) Filed: Dec. 5, 2003

(51) Int. Cl. G01R 27/26

(52) U.S. Cl. 324/662

(57) ABSTRACT

An electronic proximity sensing apparatus has at least one signal pad. The signal pads are each connected to receive an electric voltage signal. At least two sensing conductors are routed in proximity to the signal pads, and a sensor is operable to detect the difference in voltage between two of the at least two sensing conductors. Differential sensing is further applied to other capacitive proximity sensing circuits to reduce common-mode interference.

### FIELD OF THE INVENTION

The invention relates generally to electrically sensing proximity, and more specifically in one embodiment to a low noise proximity detection system using differential detection.

### BACKGROUND OF THE INVENTION

Proximity sensing, such as detecting the presence of a finger or other object with poor conductivity, can be achieved electrically through a number of existing technologies. Optical sensors can detect a change in view, or can detect an interruption in a beam of light transmitted across a detection area. Ultrasonic transceivers can gauge the distance to an acoustically solid object, such as the distance from a car's bumper to vehicles in front of or behind the car. Electrical systems can detect the presence of a capacitive body, such as wood, glass, water, oil, or a human body part such as a finger by detecting a change in capacitance or in capacitive coupling.

One such system uses a capacitor having two plates in an oscillator circuit, and measures the change in capacitance when a capacitive object comes near the capacitive plates as a change in oscillation frequency. Other such systems use other methods for detecting a change in capacitance due to proximity of a capacitive object. Another type of capacitive proximity sensor uses a driven electrode that is fed a varying voltage signal and that is located physically near a sense electrode. The voltage amplitude of the signal that is detected on the sense electrode is compared to a reference amplitude that is detected when no other capacitive object is near the electrodes, so that a change in the signal level detected on the sense electrode can be attributed to capacitive coupling between the two electrodes.

Such systems rely upon the object being detected to cause a change in capacitance observed between the two electrodes, therefore changing the level of the signal driven to one electrode that is capacitively coupled to the sense electrode. These systems are not perfect, however, as they are somewhat susceptible to noise and electromagnetic interference from surrounding electronic devices and from electrical noise present in the object being sensed. If the driven signal level is very small, the magnitude of noise that is needed to cause unreliable operation of these proximity sensors is also very small, resulting in a high probability of noise interference. If the signal is increased to a relatively large level, the electrode and its electrical connections can act as an antenna and radiate a substantial electromagnetic signal, causing interference in other electronic components and devices.

It is therefore desired that a proximity switch have good electromagnetic noise immunity, addressing the problems as described above.

### SUMMARY OF THE INVENTION

In one example embodiment of the invention, an electronic proximity sensing apparatus comprises at least one pair of signal pads, and each pair of signal pads comprises a first signal pad and a second signal pad. Each of the signal pads is connected to receive an electric voltage signal. At least two sensing conductors routed are routed between the first signal pads and the second signal pads of the pairs of signal pads, and a sensor detects the difference in voltage between at least two of the sensing conductors. In various other embodiments, differential sensing is applied to other types of capacitive proximity sensing circuits to reduce common-mode interference.

### BRIEF DESCRIPTION OF THE FIGURES

FIG. 1 shows a proximity sensing apparatus having two differential sensing conductors, consistent with an embodiment of the present invention.

FIG. 2 shows a proximity sensing apparatus having three differential sensing conductors, consistent with an embodiment of the present invention.

FIG. 3A shows a proximity sensing apparatus having a single signal pad, consistent with an embodiment of the present invention.

FIG. 3B shows an alternate configuration for a proximity sensing apparatus having a single signal pad, consistent with an embodiment of the present invention.

FIG. 4A shows a proximity sensing apparatus employing a ground shield, consistent with an embodiment of the present invention.

FIG. 4B shows a cross-section of a proximity sensing apparatus employing a ground shield, consistent with an embodiment of the present invention.

FIG. 5 illustrates a oscillator-type capacitive loading proximity sensor having differential common mode noise rejection, consistent with an embodiment of the present invention

FIG. 6 shows a charge transfer capacitive proximity sensor using differential common mode noise reduction, consistent with an embodiment of the present invention.

### DETAILED DESCRIPTION

In the following detailed description of sample embodiments of the invention, reference is made to the accompanying drawings which form a part hereof, and in which is shown by way of illustration specific sample embodiments in which the invention may be practiced. These embodiments are described in sufficient detail to enable those skilled in the art to practice the invention, and it is to be understood that other embodiments may be utilized and that logical, mechanical, electrical, and other changes may be made without departing from the spirit or scope of the present invention. The following detailed description is, therefore, not to be taken in a limiting sense, and the scope of the invention is defined only by the appended claims.

The present invention provides in various embodiments differential sensing conductors, and sensors operable to detect a voltage difference between the sensing conductors. A stimulus signal is provided via one or more single or pairs of signal pads, which are connected to receive a voltage signal. The voltage applied to the signal pads is capacitively coupled to the sensing conductors as the sensing conductors and signal pads are physically near one another, and the degree of coupling is altered by presence of a capacitive object such as a human body part. Detection of the degree of coupling by sensing changes in the voltage present in the differential sensing conductors thereby provides proximity detection of such capacitive objects.

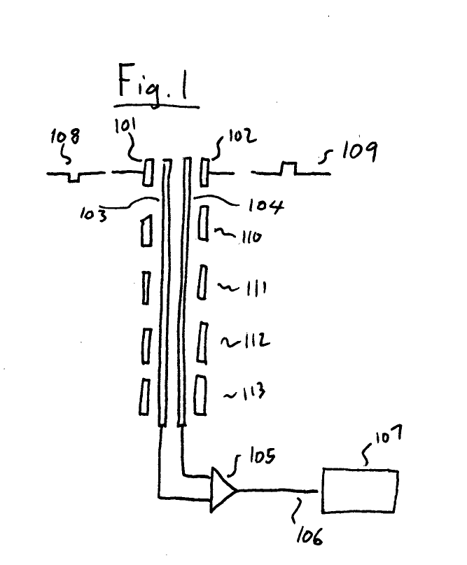

FIG. 1 illustrates an example embodiment of such a proximity sensor apparatus. A pair of signal pads is formed by first signal pad 101 and second signal pad 102. Between the signal pads are located a first sensing conductor 103 and a second sensing conductor 104, which are coupled to a sensor 105. In this embodiment, the sensor 105 is an amplifier that senses a differential voltage between sensing conductor 103 and sensing conductor 104, and provides an amplified signal representing this sensed difference as output 106. This output signal is evaluated by a control module 107, which receives the sensed difference signal 106 and determines from this signal whether a capacitive object is relatively proximate to signal pads 101 and 102.

In operation, a voltage signal 108 is applied to the first signal pad 101, and a voltage signal 109 that is the inverse of voltage signal 108 is applied to the second signal pad 102. These voltage signals cause a voltage differential to form between sensing conductors 103 and 104 due to capacitive coupling between the signal pads and the sensing conductors, resulting in a measurable voltage difference signal 106 when the changing voltage signals 108 and 109 are applied. If a capacitive object, such as glass, water, oil, or a human body part such as a finger comes into relative proximity to signal pads 101 and 102, the capacitive nature of the body contributes to capacitive coupling of sensing pads 01 and 102 to the sensing conductors 103 and 104, resulting in a measurable difference in the voltage difference signal output at 106. The control module 107 can then compare the received voltage difference output signal against an expected voltage output signal measured without a capacitive object near the signal pads to detect the presence or proximity of such an object.

When a voltage signal is provided to the signal pads 101 and 102, the signals from each of the signal pads is conducted more strongly to its nearest sensing conductor. Therefore, sensing conductor 103 receives a relatively strong signal from signal pad 101, and sensing conductor 104 receives a relatively strong signal from signal pad 102. When a capacitive object is present, the capacitive object couples more signal to the sensing conductor opposite each pad, and promotes some mixing or cancellation of signals within the capacitive object, resulting in a lesser voltage difference induced between sensing conductors 103 and 104. The capacitive object may further cause absorption or dispersion of some induced electrical energy, further reducing the induced voltage difference between sensing conductors. Sensing the drop in voltage difference between the sensing conductors 103 and 104 when a signal is presented to signal pads 101 and 102 can therefore be used to establish proximity of a capacitive object, providing proximity sensor functionality of such a system.

Electromagnetic interference affects each sensing conductor to approximately a similar degree, and can be greatly reduced by sensing the difference between the conductors rather than the absolute value of a single sensing conductor. Good common-mode interference rejection remains even when a finger or other object comes near the sensor, as the interference induced by the finger is induced approximately equally to both sensing conductors and is again easily reduced by differential sensing.

Some embodiments of the invention utilize a staggered signal pad timing system in which the signals provided to opposite signal pads such as 201 and 202 are not presented at the same time. This facilitates determination of whether a proximate capacitive object is off-axis to one side or the other relative to the sensing strips, and to what degree the object is off-center. Such a system is particularly useful in systems such as where several proximity sensing modules such as that shown in FIG. 1 are located side-by-side to form a two-dimensional array of proximity sensors, such as on a touchpad or touchscreen.

The control module is coupled to the voltage signals 108 and 109 in a further embodiment of the invention, and coordinates proximity sensing with the voltage signals supplied to multiple pairs of signal pads. For example, the voltage signal source of one embodiment first provides a voltage signal having a changing voltage or voltage pulse to pads 101 and 102. After this, a similar voltage signal is provided to the signal pads in signal pad pair 110, and then is supplied in sequence to pad pairs 111, 112, and 113. This enables the sensor 105 and the control module 107 to monitor several pairs of signal pads by knowing which pair of pads created the signal detected by sensor 105 and control module 107.

In a further embodiment of the invention, a number of proximity sensing strips such as that shown in FIG. 1 enable sensing proximity in multiple regions, and may be used for purposes such as setting input parameters for an electronic circuit. One example of such a system is an electronic audio equalizer system, having a separate group of signal pads and sensing conductors forming a one-dimensional touchpad as shown in FIG. 1 for each frequency band. The touchpad apparatus is then used to set the amplitude response for the frequency signal band corresponding to each touchpad apparatus. Further embodiments include using lights associated with the various parameter levels that can be selected via the touchpad apparatus such that the presently set level is lit, or using another similar visual indicator such as a liquid crystal display.

In another embodiment of the invention, a proximity sensor array such as that shown in FIG. 1 is able to detect an object's relative proximity to each pair of signal pads rather than simply detecting which pair of signal pads is most proximate to an object, so that interpolation between adjacent signal pads can be used to determine an object's position with greater resolution than simply the number of signal pad pairs in the array.

Various other array configurations are within the scope of the present invention, including a two-dimensional array comprising a number of proximity sensor arrays such as is shown in FIG. 1 positioned side-by-side, so that an object's position relative to the two-dimensional plane formed by the proximity sensor arrays can be determined. When such a system is combined with the ability to detect an object's relative proximity to more than one pair of signal pads, the proximity sensor arrays can detect an object in three dimensions, including an object's relative proximity to the two-dimensional array of sensors.

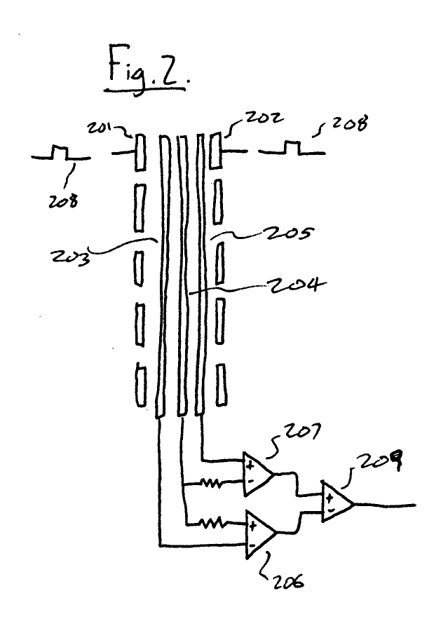

FIG. 2 shows another embodiment of a one-dimensional array of proximity sensors similar in many ways to that of FIG. 1. The most significant differences lie in that sensor pads 201 and 202 now receive the same voltage signal 208 rather than receiving signals that are the inverse of one another, and sensing conductors include three sensing conductors 203, 204, and 205 instead of just two. The center conductor 204 serves as a reference to both sensors 206 and 207, which in this diagram are differential amplifiers connected to the respective sensing conductors 203 and 205. The outputs of both amplifiers 206 and 207 are fed into differential amplifier 209, which outputs as a voltage signal the difference between the sensed differences between sensing conductors 203 to 204, and between 204 to 205. The resistors coupling center sensing conductor 204 to sensing amplifiers 206 and 207 are employed in this particular embodiment to compensate for any difference in electrical noise sensitivity between the center conductor and the adjacent sensing conductors 203 and 205, which may shield center conductor 204 to a limited extent. These resistors can be selected based on a particular layout to improve the ability of the proximity sensor apparatus to reject common mode interference or electrical noise.

In operation, the signal pads 201 and 202 are provided identical voltage signals, and induce the same voltage signal to differential sensing conductors 203 and 205, and to a lesser extent to 204 due to its greater distance from the pads and due to the shielding effect provided by sensing conductors 203 and 205. In the presence of a capacitive object, a greater amount of signal is coupled between the signal pads and the center sensing conductor 204, resulting in a lower sensed voltage difference between sensing conductors 203 and 204, and between sensing conductors 204 and 205. This reduction in sensed voltage difference indicates proximity of a capacitive object.

This configuration further has the advantage of increased noise reduction when the capacitively sensed object is not located directly over the sense elements, but is off-axis. Consider, for example, a finger nearer sensing conductors 203 and 204 than to 205. A greater amount of noise will be induced into sensing conductors 203 and 204 than to 205, but this common mode noise substantially cancels in differential sense amplifier 206. A smaller amount of noise coupled into sensing conductor 205, and sense amplifier 207 outputs a signal including the difference in noise between sensing conductors 204 and 205. This output signal is provided to differential amplifier 209 which in turn cancels remaining noise common to sensing conductor pairs 203-204 and 204-205. Therefore, the signals from the sensing conductors that have the most common mode noise will experience the greatest reduction in common noise in the first differential sensing amplifiers 206 and 207, reducing the common mode noise significantly relative to standard non-differential or to some two-sensing conductor differential capacitive proximity sensor configurations, while the second differential amplifier 209 reduces noise common to all three.

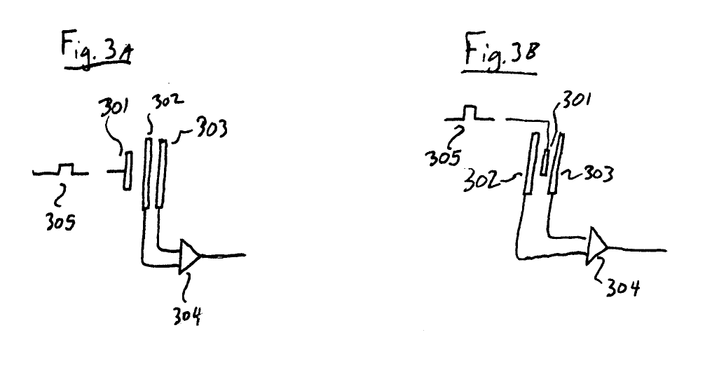

FIG. 3A shows yet another embodiment of the invention, in which a single signal pad 301 is located in proximity to differential sensing conductors 302 and 303. The differential sensing conductors are connected to sensor amplifier 304, which is operable to detect the difference in voltage between the two sensing conductors. As with the previous examples, a voltage signal 305 is applied to the signal pad 301, and the resulting voltage difference measured between sensing conductors 302 and 303 is compared to a reference voltage difference to determine whether a capacitive object is in proximity to the proximity sensor apparatus. An alternate configuration of the signal pad and differential sensing conductors is shown generally in FIG. 3B, which shows how a single signal pad 301 may be located between the differential sensing conductors 302 and 303. The simple, single button versions of the invention shown in FIGS. 3A and 3B are well suited to applications where a simple button is needed, such as in a hostile environment like a laboratory or manufacturing facility, or in a high-use environment where durability is desired, such as in an elevator.

The differential sensing conductor configuration illustrated by these examples plays an important role in decreasing the effect of electromagnetic interference on the proximity sensing apparatus. Because the differential sensing conductors are routed parallel and in proximity to one another, any interference will likely affect the sensing conductors in substantially the same way. A voltage induced in one sensing conductor by electromagnetic interference will therefore likely induce a similar voltage in neighboring, parallel sensing conductors. Determination of the difference in voltage between the sensing conductors via a sensing mechanism such as a differential amplifier will therefore result in relatively little electromagnetic interference sensed, as only the difference between voltages in the sensing conductors is measured. Although the signal pads and differential sensing conductors are parallel strips in many of the example embodiments illustrated, they can take other forms in various other embodiments of the invention, including circular signal pads or circular differential sensing pads.

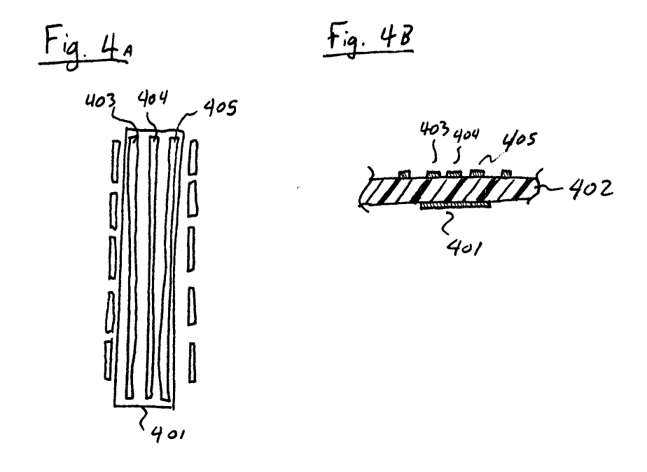

Grounded shield strips are incorporated in various further embodiments of the present invention to improve resistance to electromagnetic interference by shielding the sensing conductors of the various embodiments of the invention from electromagnetic interference such as induced electrical noise. These grounded strips conduct the interference in their relative proximity to ground, reducing the amount of electromagnetic interference reaching the sensing conductors. FIG. 4 shows generally how grounding strips 401 can be employed to shield a proximity sensor array such as that of FIG. 2. The large, grounded copper pad 401 is formed on a layer of a printed circuit board 402, positioned directly below the sensing conductors 403, 404, and 405. In some embodiments of the invention, the grounded pad 401 is formed on a power distribution layer or ground layer of a multi-layer printed circuit board, and uses a dedicated grounded return signal path to a central grounded location to drain induced electric signals caused by electromagnetic interference.

The voltages induced on the differential sensing conductors are sensed by differential amplifiers such as 105 of FIG. 1, and provide the sensed voltage to a control module such as 107 in some embodiments of the invention. The control module receives the signal, and compares the sensed voltage signal to the expected voltage signal to estimate or determine proximity of a capacitive object. In some further embodiments, a degree of hysteresis is built in to the control module in proximity sensors having multiple pads or pairs of pads such as is shown in FIG. 1.

In operation, when an object such as a user's finger comes into proximity to one of the pairs of signal pads in FIG. 1, the threshold for detection of an object and determination of the object's presence is reduced, to ensure that as the object moves about the proximity sensing apparatus from one pair of pads to another, the proximity sensor remains actively tracking the object. Without a hysteresis system such as this built in to the control module, an apparatus such as that of FIG. 1 used for a finger-actuated control would be more susceptible to losing track of a finger as it slid up and down in proximity to the differential sensing strips from one pair of pads to another. The inclusion of hysteresis therefore provides relatively smooth and reliable operation of a proximity sensor apparatus such as that of FIGS. 1 and 2 for touch-actuated controllers. Further embodiments use hysteresis even with a single proximity sensor, to eliminate “bounce” and ensure that a single touch actuates the switch a single time.

Digital sampling of the received signal within the control module 107 enables performance of these methods and others within a digital processor, simplifying in some embodiments operation of the control module. Sampling the signal also enables various filtering techniques, both digital and analog, to be applied to the received signal to shape the frequency response of the sensing system and further improve noise immunity. The most recently sensed or touched level in a multi-pad or multi-pair sensing apparatus such as that of FIGS. 1 and 2 is in some embodiments stored in a memory, so that the selected position of a controller can be held once it is no longer being touched. Such a system also enables loading a preset value or setting an initial state via the memory, so that presets or electronic control of settings can be achieved.

One example of an application in which such a system is desirable is to provide control of settings on an electronic music keyboard or synthesizer. Various parameters such as attack, decay, envelope, oscillator frequency, waveform control, volume level and such are used to define the nature of the sound being synthesized, and can be readily set via presets from memory, and actively controlled by a user using proximity sensing apparatus such as that of FIGS. 1 and 2 to alter the characteristics of the synthesized sound. The present invention is easily adapted to a wide variety of other such systems as a parameter control or selection module.

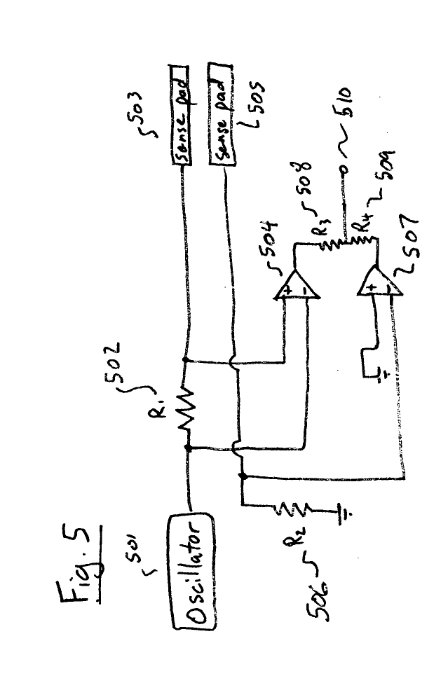

FIG. 5 illustrates a oscillator-driven capacitive loading proximity sensor having differential common mode noise rejection, consistent with an embodiment of the present invention. An oscillator 501 is connected via a resistor R1 shown at 502 to a first sense pad 503. An amplifier 504 is connected across the resistor 502, providing an output signal proportional to the voltage drop across the resistor 502. Prior art versions of this type of proximity sensor typically contain no more elements than these elements 501-504, and do nor provide differential sensing. In this example embodiment of the present invention, a second sense pad 505 is located in physical proximity to the first sense pad 503, and is similarly configured. The second sense pad is coupled to ground via a resistor R2, shown at 506. An amplifier 507 is coupled across the resistor 506, and its output varies with the voltage drop across resistor R2. The outputs of amplifiers 504 and 507 are coupled via resistors 508 and 509 to an output 510, which provides a signal that varies with proximity of a capacitively coupled object to the sense pads 503 and 505, but which uses the differential sensing circuit shown here to cancel noise common to both sense pads 503 and 505 from the output signal 510.

The sense pads are in some embodiments of the invention configured to sense certain capacitive objects, such as a human finger. Because noise immunity is greater in some variations when the pads are configured physically near each other and are physically similar in size, shape, and orientation, the pads are further configured to be similar and near to one another. When sensing a finger, for example, it is desired that the distance between sense pads not be significantly greater than the width of a finger, but is instead desired to be only somewhat bigger than or smaller than the width of a finger. This physical proximity increases the likelihood that the sense pads will be equally subject to the same noise and interference signal, increasing the effectiveness of the differential common mode noise elimination of the present invention.

In operation, the oscillator 501 provides a signal, such as a 100 kHz sine wave, through R1 to the sense pad 503. The sense pad 503 capacitively couples to a nearby capacitive proximate object when such an object is near, thereby introducing a capacitive load to the oscillator 501. This can be measured as an increased voltage drop across resistor 502, which is sensed by amplifier 504. Although this is sufficient to detect proximity of such an object, the present invention further uses a sense pad 505 to detect common mode noise, which is sensed via amplifier 507 as a voltage difference across resistor 506, which is in some embodiments similar in resistance to the resistor 502 or to the impedance as seen by the sense pad 503 such as may be formed by resistor 502, oscillator 501, and amplifier 504. Because the amplifier 507 amplifies noise present on pad 505 opposite in polarity to amplifier 504's amplification of noise sensed in sense pad 503, the signals from amplifiers 504 and 507 can be combined to substantially eliminate noise that is common to both sense pads 503 and 505. In the example circuit of FIG. 5, this is done by coupling both amplifier outputs via resistors 508 and 509 to the output 510. In a further embodiment of the invention, the gain of at least one of amplifier 504 and 507 is adjustable or is pre-configured to substantially eliminate common mode noise sensed by sense pads 503 and 505.

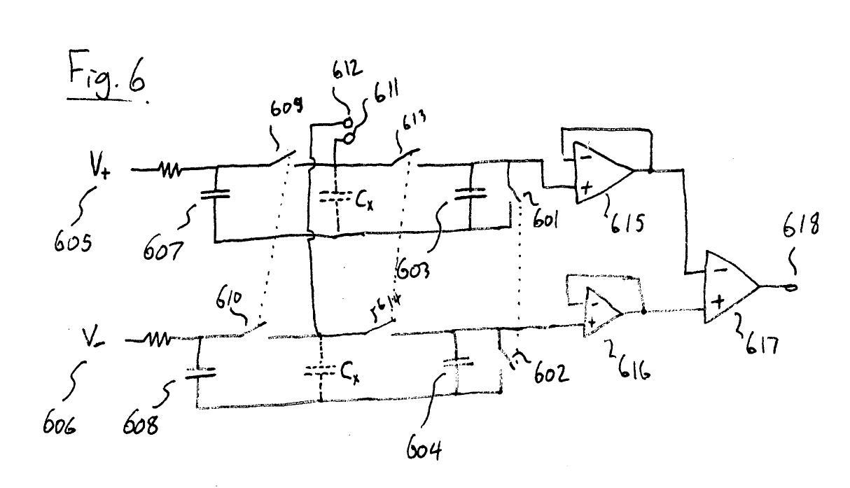

FIG. 6 shows a charge transfer capacitive proximity sensor using differential common mode noise reduction, consistent with an embodiment of the present invention. To initiate a proximity sensing sequence, switches 601 and 602 are closed and then re-opened, to ensure that capacitors 603 and 604 are fully discharged. The switches in some embodiments of the invention will be transistors, such as FET transistors, that are momentarily brought into a conducting state from a nonconducting state. The capacitors are in some embodiments preferred to be capacitors with a low dielectric absorption, such as polypropylene, mylar, polystyrene, or teflon dielectric, with a film and foil or metallized film construction. The voltage at 605 and the inverse voltage at 606 are supported by bypass capacitors 607 and 608, which serve to minimize local voltage fluctuations. These voltages are applied to virtual capacitances Cx by switching switches 609 and 610 to a closed position for a period of time sufficient to charge the virtual capacitances Cx, formed by proximity of a capacitive object to capacitive proximity sense pads 611 and 612.

Once the virtual capacitances Cx of the capacitive proximity sense pads are charged to a known voltage, switches 609 and 610 are opened, and switches 613 and 614 are momentarily closed. The switches 613 and 614 are closed long enough for the voltage at the virtual capacitances Cx and the sense capacitors 603 and 604 to become substantially similar. The capacitors 603 and 604 are therefore preferably significantly larger in capacitance than the expected maximum size of the virtual capacitance Cx.

Next, switches 613 and 614 are opened, and the voltage at capacitors 603 and 604 are measured. Because capacitors 603 and 604 are of known capacitance and are known to be charged to the same voltage as were virtual capacitances Cx at the time switches 613 and 614 were closed, the voltages measured across capacitors 603 and 604 will be approximately proportional to the capacitance of virtual capacitors Cx. This occurs because although Cx was charged to a known voltage earlier, the actual charge it received was dependent both on the applied voltage and its capacitance, as governed by the formula Q=CV, where Q=charge in coulombs, C=capacitance, and v=applied voltage. The final voltage that appears on capacitors 603 and 604 is therefore dependent on both the known applied voltage and the unknown capacitance of Cx, Detection of a higher-than-expected voltage across capacitors 603 and 604 therefore indicates a higher than expected virtual capacitance Cx, indicating the proximity of a capacitive object to capacitive proximity sensing pads 611 and 612.

The sensed voltages are fed into amplifiers 615 and 616, which in some embodiments of the invention have a high input impedance to avoid rapidly draining the charge of capacitors 603 and 604. The outputs from amplifiers 615 and 616, which form differential capacitive proximity sensing circuits, are fed into differential amplifier 617, which serves to eliminate common-mode noise sensed by both capacitive sense pads 611 and 612. Its output 618 therefore provides a voltage signal indicating relative proximity of a capacitive object, but with improved immunity to common mode noise than would a non-differential circuit such as simply the top half of the circuit of FIG. 6.

In some further embodiments, amplifiers 615 and 616 can be eliminated from the circuit, and a single amplifier 617 having a high input impedance is employed. Further, as only either the top half or the bottom half of the circuit of FIG. 6 is needed to sense proximity, the opposite half can in some embodiments not include a voltage source, bypass capacitor 607 or 608, and switch 609 or 610. As long as the sense portion of the circuit is configured to convey common mode noise from the sense pad 611 or 612 in substantially the same way as in the other half of the circuit, its purpose of sensing common mode noise for differential cancellation can be achieved.

The circuit of FIG. 6 is provided with input signals that are opposite in voltage and sensed signals that are of the same phase, but various embodiments of the present invention will operate significantly better when the phase of one or more of the sensed signals is inverted before being provided to the one or more differential sensing amplifiers. An example of such is illustrated and explained in greater detail in conjunction with FIG. 2. The inversion provides the intended result of a greater difference signal between the two sensors representing the capacitive sensed proximity signal, and a common-mode signal representing noise common to the one or more sensed signals that can be greatly reduced by differential sensing circuitry.

These examples illustrate further ways in which the present invention can be applied to capacitive proximity sensing, using differential sensing to reduce common mode noise in the sensed proximity signal. A variety of systems, including linear differential sensing strips, linear parallel pads, charge transfer sensors, and oscillator-driven sense pads may be employed to practice the present invention, but the invention is not so limited. Various other formats are contemplated, including but not limited to variations in differential sensing conductor and signal pad configurations, embodiments where signal pads and differential sensing conductors are placed on different levels of a circuit board, and within mediums other than a circuit board, such as implementation as transparent conductors overlaying a screen of a Personal Digital Assistant, cellular telephone, video or computer monitor, or other such device.

Although specific embodiments of proximity sensors having differential sensing conductors have been illustrated and described herein, it will be appreciated by those of ordinary skill in the art that any arrangement which is calculated to achieve the same purpose may be substituted for the specific embodiments shown. This application is intended to cover any adaptations or variations of the invention. It is intended that this invention be limited only by the claims, and the full scope of equivalents thereof.

1. An electronic proximity sensing apparatus, comprising:
at least two pair of signal pads, each pair of signal pads comprising a first signal pad and a second signal pad, each signal pad connected to receive an electric voltage signal;
at least two sensing conductors routed between the first signal pads and the second signal pads of the at least two pair of signal pads; and
a sensor operable to detect the difference in voltage between two of the at least two sensing conductors.

2. The electronic proximity sensing apparatus of claim 1, wherein the first signal pad and the second signal pad of each pair are connected to receive electric voltage signals that vary inversely to one another.

3. The electronic proximity sensing apparatus of claim 1, wherein the electric voltage applied to each pair of the at least two pair of signal pads varies only when the voltage applied to other pair of the at least two pair of signal pads remains substantially constant.

4. The electronic proximity sensing apparatus of claim 1, wherein the at least two sensing conductors comprise printed circuit board traces that are substantially parallel to each other, and wherein the at least two pair of signal pads comprise signal pads comprising printed circuit board traces running substantially parallel to one another and to the at least two sensing conductors.

5. The electronic proximity sensing apparatus of claim 1, wherein the at least two sensing conductors are physically separated by a ground conductor at a ground potential voltage.

6. The electronic proximity sensing apparatus of claim 1, wherein the at least two sensing conductors comprise at least three sensing conductors, and wherein the sensor comprises:
a first sensor operable to detect a voltage between a first of the at least three sensing conductors and a second of the at least three sensing conductors and to output a voltage signal proportional to the detected voltage;
a second sensor operable to detect a voltage between the second of the at least three sensing conductors and a third of the at least three sensing conductors and to output a voltage signal proportional to the detected voltage; and
a third sensor operable to detect a difference between the voltages output by the first sensor and the second sensor, and to output a voltage signal proportional to the detected voltage difference.

7. The electronic proximity sensing apparatus of claim 1, wherein the electronic proximity sensing apparatus comprises part of a position selector apparatus, and wherein each pair of signal pads represents a position of the position selector apparatus.

8. The electronic proximity sensing apparatus of claim 1, further comprising at least two visual indicators associated with the at least two pair of signal pads, the visual indicators configured to provide visual indication of signal pads actuated by proximity sensing.

9. The electronic proximity sensing apparatus of claim 1, further comprising a circuit coupled to the sensor for comparing the detected voltage difference to an anticipated voltage difference to determine proximity of a capacitive body.

10. The electronic proximity sensing apparatus of claim 9, wherein a detected voltage difference significantly lower than the anticipated voltage difference indicates proximity of a capacitive body.

11. The electronic proximity sensing apparatus of claim 9, wherein the capacitive body is part of a human body.

12. The proximity sensing apparatus of claim 1, comprising multiple proximity sensing apparatus configured to form a two-dimensional touchpad proximity sensing apparatus.

13. The proximity sensing apparatus of claim 1, wherein sensing proximity comprises determining whether an object is proximate or not proximate.

14. The proximity sensing apparatus of claim 1, wherein sensing proximity comprises determining a varying degree of proximity of an object.

15. The proximity sensing apparatus of claim 1, wherein the sensing proximity comprises evaluation of proximity sensing data from at least two of the at least two pair of signal pads to provide an interpolated detected proximity location.

16. The proximity sensing apparatus of claim 1, further comprising an audio synthesizer, wherein the proximity sensing apparatus is coupled to the proximity sensor such that the proximity sensor is operable to control one or more synthesizer parameters.

17. An electronic proximity sensing apparatus, comprising:
at least one signal pad, each signal pad configured to receive an electric voltage signal;
at least two sensing conductors physically positioned in proximity to the at least one signal pad, the sensing conductors not in electrical contact with the at least one signal pad; and
a sensor operable to detect the difference in voltage between two of the at least two sensing conductors, thereby sensing proximity of an object.

18. The electronic proximity sensing apparatus of claim 17, wherein the at least one signal pad comprises a first and second signal pad forming a pair, and wherein the at least two sensing conductors are routed between the first and second signal pad.

19. A method of sensing proximity of an object, comprising:
providing an electrical signal to at least two pair of signal pads, each pair of signal pads comprising a first signal pad and a second signal pad; and
sensing a difference in voltage between at least two sensing conductors routed between the first signal pads and the second signal pads of the at least two pair of signal pads.

20. The method of sensing proximity of an object of claim 19, wherein the first signal pad and the second signal pad of each pair are provided electric voltage signals that vary inversely to one another.

21. The method of sensing proximity of an object of claim 19, wherein the electrical signal provided to each pair of the at least two pair of signal pads varies only when the electrical signal applied to other pair of the at least two pair of signal pads remains substantially constant.

22. The method of sensing proximity of an object of claim 19, wherein the at least two sensing conductors comprise printed circuit board traces that are substantially parallel to each other, and wherein the at least two pair of signal pads comprise signal pads comprising printed circuit board traces running substantially parallel to one another and to the at least two sensing conductors.

23. The method of sensing proximity of an object of claim 19, wherein the at least two sensing conductors are physically separated by a ground conductor at a ground potential voltage.

24. The method of sensing proximity of an object of claim 19, wherein the at least two sensing conductors comprise at least three sensing conductors, and wherein the sensor comprises:
a first sensor operable to detect a voltage between a first of the at least three sensing conductors and a second of the at least three sensing conductors and to output a voltage signal proportional to the detected voltage;
a second sensor operable to detect a voltage between the second of the at least three sensing conductors and a third of the at least three sensing conductors and to output a voltage signal proportional to the detected voltage; and
a third sensor operable to detect a difference between the voltages output by the first sensor and the second sensor, and to output a voltage signal proportional to the detected voltage difference.

25. The method of sensing proximity of an object of claim 19, wherein the at least two pair of signal pads and the at least two sensing conductors comprise part of a position selector apparatus, and wherein each pair of signal pads represents a position of the position selector apparatus.

26. The method of sensing proximity of an object of claim 19, further comprising operating at least two visual indicators associated with the at least two pair of signal pads to provide visual indication of actuation of the signal pads by proximity sensing.

27. The method of sensing proximity of an object of claim 19, further comprising comparing the detected voltage difference to an anticipated voltage difference to determine proximity of a capacitive body.

28. The method of sensing proximity of an object of claim 27, wherein determining proximity of a capacitive body when a detected voltage difference significantly lower than the anticipated voltage difference is detected.

29. The method of sensing proximity of an object of claim 27, wherein the capacitive body is part of a human body.

30. The method of sensing proximity of an object of claim 19, wherein the signal pads and sensing conductors are configured to form a two-dimensional touchpad proximity sensing apparatus.

31. The method of sensing proximity of an object of claim 19, wherein sensing proximity comprises determining whether an object is proximate or not proximate.

32. The method of sensing proximity of an object of claim 19, wherein sensing proximity comprises determining a varying degree of proximity of an object.

33. The method of sensing proximity of an object of claim 19, wherein the sensing proximity comprises evaluation of proximity sensing data from at least two of the at least two pair of signal pads to provide an interpolated detected proximity location.

34. A method of sensing proximity of an object, comprising:
providing a changing electric voltage signal to at least one signal pad; and
detecting a difference in voltage between two of at least two sensing conductors routed substantially parallel to one another and in proximity to the at least one signal pad, the sensing conductors not electrically coupled to the at least one signal pad.

35. The method of sensing proximity of an object of claim 34, wherein the at least one signal pad comprises a first and second signal pad forming a pair, and wherein the at least two sensing conductors are routed between the first and second signal pad.

36. An electronic proximity sensing apparatus, comprising:
at least two sensing pads, the at least two sensing pads being substantially similar in size and configuration to one another;
at least one signal source, the signal source either electrically coupled to at least one of the two sensing pads or coupled to at least one signal pad in proximity to the at least two sensing pads; and
a sensor operable to detect the difference in voltage between two of the at least two sensing pads, thereby sensing proximity of an object.

37. The electronic proximity sensing apparatus of claim 36, wherein the at least two sensing pads are in proximity to each other relative to the size of the object which the proximity sensing apparatus is configured to sense.

38. The electronic proximity sensing apparatus of claim 37, wherein the at least two sensing pads are closer in distance than the approximate width of the object to be sensed.

39. The electronic proximity sensing apparatus of claim 37, wherein the object the electronic proximity sensing apparatus is configured to sense is a human finger.

40. The electronic proximity sensing apparatus of claim 36, wherein the at least two sensing pads are in proximity to the at least one signal pad relative to the approximate size of the object the electronic proximity sensing apparatus is configured to sense.

41. The electronic proximity sensing apparatus of claim 40, wherein the at least two sensing pads and the at least one signal pad are closer in distance than the approximate width of the object to be sensed.

42. The electronic proximity sensing apparatus of claim 40, wherein the object the electronic proximity sensing apparatus is configured to sense is a human finger.

43. The electronic proximity sensing apparatus of claim 36, wherein the at least one signal source comprises an oscillator signal coupled via a resistor to at least one of the at least two sensing pads.

44. The electronic proximity sensing apparatus of claim 36, wherein the at least one signal source comprises at least one charge transfer circuit coupled to at least one of the at least two sensing pads.

45. The electronic proximity sensing apparatus of claim 44, wherein the at least one signal source further comprises a second charge transfer circuit coupled to at least a second of the at least two sensing pads.

46. The electronic proximity sensing apparatus of claim 36, wherein the sensor comprises a sense amplifier connected to each of the at least two sensing pads.

47. The electronic proximity sensing apparatus of claim 46, wherein the sense amplifiers are each configured to have a substantially similar input impedance.

48. The electronic proximity sensing apparatus of claim 46, wherein the sense amplifiers are gain-adjusted to amplify common mode noise sensed via the coupled sense pads by substantially the same amount.

49. The electronic proximity sensing apparatus of claim 36, wherein the at least two sensing pads comprise at least three sensing pads, and wherein the sensor comprises:
a first sensor operable to detect a voltage between a first of the at least three sensing pads and a second of the at least three sensing pads and to output a voltage signal proportional to the detected voltage;
a second sensor operable to detect a voltage between the second of the at least three sensing pads and a third of the at least three sensing pads and to output a voltage signal proportional to the detected voltage; and
a third sensor operable to detect a difference between the voltages output by the first sensor and the second sensor, and to output a voltage signal proportional to the detected voltage difference.

50. A method of detecting proximity of a capacitive object, comprising:
providing an electric stimulus signal to a region having least two sensing pads;
sensing an electric signal from a first sensing pad, the electric signal indicating proximity of a capacitive body;
sensing an electric signal from a second sensing pad, the second sensing pad located physically near the first sensing pad and similar in physical configuration to the first sensing pad, and the electric signal indicating proximity of a capacitive body; and
differentially combining the sensed electric signals from the first sensing pad and the second sensing pad such that common mode noise is reduced.
